(19) United States
(12) Patent Application Publication
(10) Pub. No.: US 2009/0242025 A1
(43) Pub. Date: Oct. 1, 2009

(54) Thin film type solar cell, and method for manufacturing the same

(75) Inventor: Jae Ho Kim, Yongin-si (KR)

Correspondence Address: Royal W. Craig;Ober, Kaler, Grimes & Shriver, 120 East Baltimore Street, Baltimore, MD, 21202-1643, US

(73) Assignee: JUSUNG Engineering Co., Ltd., Gwangju-si (KR)

(21) Appl. No.: 12/383,642

(22) Filed: Mar. 26, 2009

(30) Foreign Application Priority Data
Mar. 27, 2008 (KR) 10-2008-0028187

(51) Int. Cl. H01L 31/00; H01L 21/00

(52) U.S. Cl. 136/256; 438/98; 257/E21.002

(57) ABSTRACT

A thin film type solar cell and a method for manufacturing the same is disclosed, wherein the thin film type solar cell comprises a substrate; a plurality of front electrodes formed on the substrate at fixed intervals by each first separating channel interposed in-between; a semiconductor layer formed on the front electrodes, the semiconductor layer having a contact portion therein; and a plurality of rear electrodes formed at fixed intervals by each second separating channel interposed in-between, and electrically connected with the front electrode through the contact portion, wherein the rear electrode is comprised of a first rear electrode and a plurality of second rear electrodes branching from the first rear electrode, wherein the first rear electrode is formed along a first direction, and the plurality of second rear electrodes extend from the first rear electrode and are arranged at a second direction which is different from the first direction, so that it is possible to obtain a predetermined visible range by transmitting the solar ray through the portion between each of the second rear electrodes.

### CROSS REFERENCE TO RELATED APPLICATIONS

This application claims the benefit of the Korean Patent Application No. P2008-0028187, filed on Mar. 27, 2008, which is hereby incorporated by reference as if fully set forth herein.

### BACKGROUND OF THE INVENTION

1. Field of the Invention

The present invention relates to a thin film type solar cell, and more particularly, to a thin film type solar cell with a plurality of unit cells connected in series.

2. Discussion of the Related Art

A solar cell with a property of semiconductor converts a light energy into an electric energy.

A structure and principle of the solar cell according to the related art will be briefly explained as follows. The solar cell is formed in a PN-junction structure where a positive (P)-type semiconductor makes a junction with a negative (N)-type semiconductor. When a solar ray is incident on the solar cell with the PN-junction structure, holes (+) and electrons (−) are generated in the semiconductor owing to the energy of the solar ray. By an electric field generated in a PN-junction area, the holes (+) are drifted toward the P-type semiconductor and the electrons (−) are drifted toward the N-type semiconductor, whereby an electric power is produced with an occurrence of electric potential.

The solar cell can be largely classified into a wafer type solar cell and a thin film type solar cell.

The wafer type solar cell uses a wafer made of a semiconductor material such as silicon. In the meantime, the thin film type solar cell is manufactured by forming a semiconductor in type of a thin film on a glass substrate.

With respect to efficiency, the wafer type solar cell is better than the thin film type solar cell. However, in the case of the wafer type solar cell, it is difficult to realize a small thickness due to difficulty in performance of the manufacturing process. In addition, the wafer type solar cell uses a high-priced semiconductor substrate, whereby its manufacturing cost is increased.

Even though the thin film type solar cell is inferior in efficiency to the wafer type solar cell, the thin film type solar cell has advantages such as realization of thin profile and use of low-priced material. Accordingly, the thin film type solar cell is suitable for a mass production.

The thin film type solar cell is manufactured by sequential steps of forming a front electrode on a glass substrate, forming a semiconductor layer on the front electrode, and forming a rear electrode on the semiconductor layer. In this case, since the front electrode corresponds to a light-incidence face, the front electrode is made of a transparent conductive material, for example, ZnO. With the increase in size of substrate, a power loss increases due to a resistance of the transparent conductive layer.

Thus, a method for minimizing the power loss has been proposed, in which the thin film type solar cell is divided into a plurality of unit cells connected in series. This method enables the minimization of power loss caused by the resistance of the transparent conductive material.

Hereinafter, a related art method for manufacturing a thin film type solar cell with a plurality of unit cells connected in series will be described with reference to FIG. 1(A to F).

FIG. 1(A to F) is a series of cross section views illustrating a related art method for manufacturing a thin film type solar cell with a plurality of unit cells connected in series.

First, as shown in FIG. 1(A), a front electrode layer 20a is formed on a substrate 10.

Next, as shown in FIG. 1(B), a plurality of front electrodes 20 are formed by removing predetermined portions of the front electrode layer 20a through a laser-scribing process, wherein the plurality of front electrodes 20 are provided at fixed intervals each separated by first separating channels 25 interposed in-between.

Then, as shown in FIG. 1(C), a semiconductor layer 30a and a transparent conductive layer 40a are sequentially formed on an entire surface of the substrate 10.

As shown in FIG. 1(D), the semiconductor layer 30 and transparent conductive layer 40 are formed by removing predetermined portions from the semiconductor layer 30a and transparent conductive layer 40a through a laser-scribing process, wherein the semiconductor layer 30 and transparent conductive layer 40 have contact channels 35 formed therein.

As shown in FIG. 1(E), a rear electrode layer 50a is formed on the entire surface of the substrate 10.

As shown in FIG. 1(F), second separating channels 45 are formed by removing predetermined portions of the semiconductor layer 30, transparent conductive layer 40, and rear electrode layer 50a through a laser-scribing process. Thus, a plurality of rear electrodes 50 are formed at fixed intervals and separated from each other by second separating channels 45 interposed in-between.

FIG. 2 is a plane view illustrating a related art thin film type solar cell manufactured by the process according to the series of FIG. 1(A to F), which shows the front electrode 20 and the rear electrode 50.

As shown in FIG. 2, the plurality of front electrodes 20 (dotted line) are provided at fixed intervals by each first separating channel 25 interposed in-between. Also, the plurality of rear electrodes 50 (solid line) are provided at fixed intervals by each second separating channel 45 interposed in-between while being connected with the front electrode 20 through the contact part.

Such thin film type solar cells have been developed for various purposes. Especially, there is an attempt to utilize the thin film type solar cell as the exterior of building. In case of the building in the related art, transparent glass is used for the exterior of building so as to obtain visibility, and an additional apparatus for concentrating the solar ray is provided on the roof of the building. In this case, the additional provision of the apparatus may cause the increase of cost. When the thin film type solar cell is used for the exterior of building, total cost can be decreased.

If the thin film type solar cell in itself is used for the exterior of building, it is necessary for the thin film type solar cell to include light-transmittance parts so as to obtain visibility. In case of the related art thin film type solar cell shown in FIG. 2, since the rear electrode 50 which is made of an opaque metal material is formed on the most part of the substrate, it is difficult to obtain visibility.

### SUMMARY OF THE INVENTION

Accordingly, the present invention is directed to a thin film type solar cell and a method for manufacturing the same that substantially obviates one or more problems due to limitations and disadvantages of the related art.

An object of the present invention is to provide a thin film type solar cell and a method for manufacturing the same, which is capable of obtaining a predetermined visible range suitable for the exterior of building.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a thin film type solar cell comprises a substrate; a plurality of front electrodes formed on the substrate at fixed intervals and each separated by a first separating channel interposed in-between; a semiconductor layer formed on the front electrodes, the semiconductor layer having a contact part therein; and a plurality of rear electrodes formed at fixed intervals and each separated by a second separating channel interposed in-between, and electrically connected with the front electrode through the contact part, wherein the rear electrode is comprised of a first rear electrode and a plurality of second rear electrodes, wherein the first rear electrode is formed at a first direction, and the plurality of second rear electrodes extend from the first rear electrode and are arranged at a second direction which is different from the first direction.

In another aspect of the present invention, a method for manufacturing a thin film type solar cell comprises the steps of forming a plurality of front electrodes on a substrate, wherein the plurality of front electrodes are formed at fixed intervals by each first separating channel interposed in-between; forming a semiconductor layer on an entire surface of the substrate; forming a contact portion by removing a predetermined portion of the semiconductor layer; and forming a plurality of rear electrodes at fixed intervals by each second separating channel interposed in-between, and electrically connected with the front electrode through the contact portion, wherein the rear electrode is comprised of a first rear electrode and a plurality of second rear electrodes, wherein the first rear electrode is formed at a first direction, and the plurality of second rear electrodes extend from the first rear electrode and are arranged at a second direction which is different from the first direction.

In another aspect of the present invention, a method for manufacturing a thin film type solar cell comprises the steps of forming a plurality of front electrodes on a substrate, wherein the plurality of front electrodes are formed at fixed intervals by each first separating channel interposed in-between; forming a semiconductor layer on an entire surface of the substrate; forming an open part by removing a predetermined portion of the semiconductor layer; and forming a plurality of rear electrodes, wherein the rear electrode is connected with one portion of each open part, and the plurality of rear electrodes are formed at fixed intervals by the remaining portion of each open part interposed in-between, wherein the rear electrode is comprised of a first rear electrode and a plurality of second rear electrodes, wherein the first rear electrode is formed at a first direction, and the plurality of second rear electrodes extend from the first rear electrode and are arranged at a second direction which is different from the first direction.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1(A to F) is a series of cross section views illustrating a related method for manufacturing a thin film type solar cell;

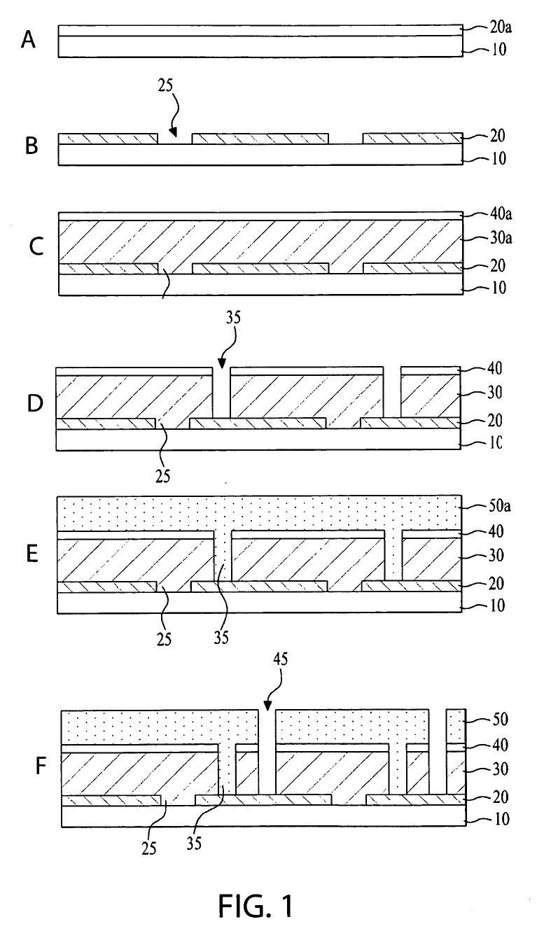

FIG. 2 is a top plan view illustrating the thin film type solar cell according to the related method in FIG. 1;

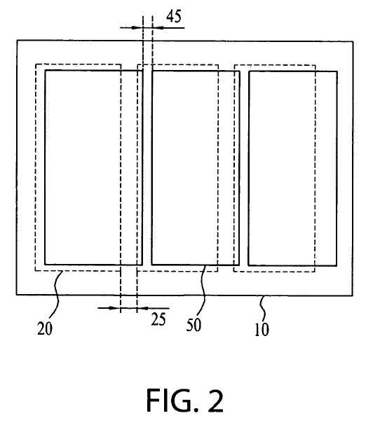

FIG. 3(A) is a top plan view illustrating a thin film type solar cell according to one embodiment of the present invention, FIG. 3(B) is a cross section view along A-A of FIG. 3(A) according to one embodiment of the present invention, and FIG. 3(C) is a cross section view along A-A of FIG. (3A) according to another embodiment of the present invention;

FIG. 4(A to F) is a series of cross section views illustrating a method for manufacturing a thin film type solar cell according to one embodiment of the present invention;

FIG. 5(A to E) is a series of cross section views illustrating a method for manufacturing a thin film type solar cell according to another embodiment of the present invention; and

FIG. 6(A to D) is a series of cross section views illustrating a method for manufacturing a thin film type solar cell according to another embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a thin film type solar cell according to the present invention and a method for manufacturing the same will be described with reference to the accompanying drawings.

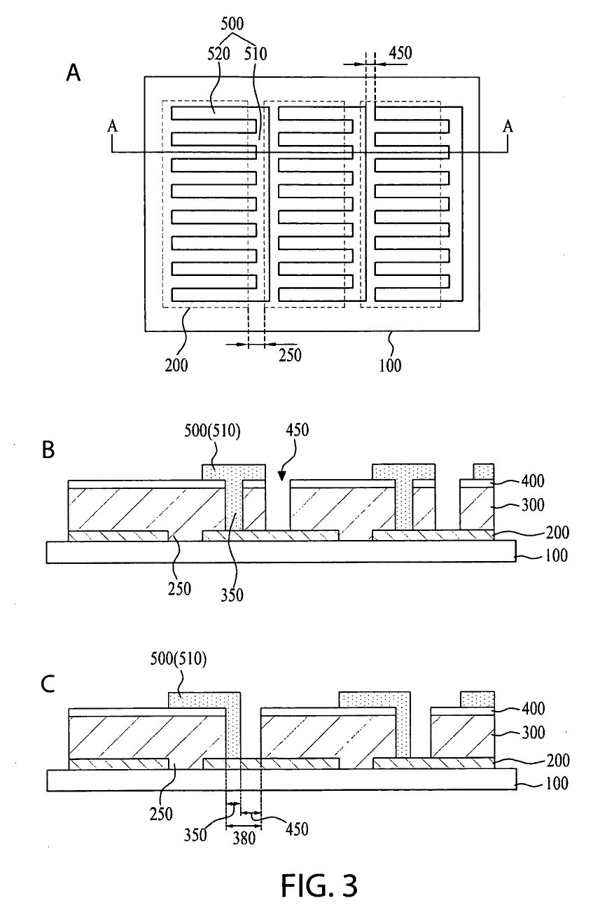

FIG. 3(A) is a plane view illustrating a thin film type solar cell according to one embodiment of the present invention, FIG. 3(B) is a cross section view along A-A of FIG. 3A according to one embodiment of the present invention, and FIG. 3(C) is a cross section view along A-A of FIG. 3(A) according to another embodiment of the present invention.

A front electrode and a rear electrode in the thin film type solar cell according to the present invention will be firstly explained with reference to FIG. 3(A), and other elements in the thin film type solar cell according to the present invention will be explained with reference to FIG. 3(B) and FIG. 3(C).

FIG. 3(A) is the top plan view illustrating the thin film type solar cell according to the present invention, which shows the front electrode 200 (indicated by a dotted line) and the rear electrode 500 (indicated by a solid line).

As shown in FIG. 3(A), the plurality of front electrodes 200 are formed on a substrate 100, wherein the plurality of front electrodes 200 are formed at fixed intervals and are separated by a first separating channel 250 interposed in-between. Also, the plurality of rear electrodes 500 are formed over the front electrodes 200, wherein the plurality of rear electrodes 500 are formed at fixed intervals and are separated by a second separating channel 450 interposed in-between.

The rear electrode 500 is comprised of a first rear electrode 510 and a plurality of second rear electrodes 520 branching as fingers from the first rear electrode 510. The first rear electrode 510 is formed to extend along a first direction, and the second rear electrodes 520 are formed to extend at fixed intervals along a second direction different from the first direction, wherein the plurality of second rear electrodes 520 extend from and intersect with the first rear electrode 510.

At this time, the first rear electrode 510 is in contact with the front electrode 200 through a contact portion, whereby the rear electrode 500 is electrically connected with the front electrode 200. Also, since the plurality of second rear electrodes 520 are arranged at fixed intervals, a solar ray can penetrate through the fingers between each of the second rear electrodes 520, so that it is possible to obtain a predetermined visible range.

As a total area of the second rear electrodes 520 is decreased, the transmittance of solar rays increases since the visible range is widened. However, if the total area of the second rear electrodes 520 is too small, carriers can not move stably, thereby lowering solar cell efficiency. Accordingly, in consideration for the visible range and solar cell efficiency, the total area of the second rear electrodes 520 should be adjusted properly. The total area of the second rear electrodes 520 can be adjusted properly by adjusting the interval between each of the second rear electrodes 520.

As shown in FIG. 3(B) and FIG. 3(C), the thin film type solar cell according to the present invention includes the substrate 100, the front electrode 200, a semiconductor layer 300, a transparent conductive layer 400, and the rear electrode 500.

The substrate 100 may be made of glass or transparent plastic.

The plurality of front electrodes 200 are formed at fixed intervals by each first separating channel 250 interposed in-between. The front electrode 200 may be formed of a transparent conductive material, for example, ZnO, ZnO:B, ZnO:Al, SnO₂, SnO₂:F, or ITO (Indium Tin Oxide). The front electrode 200 corresponds to a solar-ray incidence face. In this respect, it is important for the front electrode 200 to transmit the solar ray into the inside of the solar cell with the maximized absorption of solar ray. For this, the front electrode 200 may have an uneven surface. If forming the uneven surface in the front electrode 200, a solar-ray reflection ratio on the solar cell is decreased and a solar-ray absorbing ratio on the solar cell is increased owing to a dispersion of the solar ray, thereby improving the solar cell efficiency.

The semiconductor layer 300 is formed on the front electrodes 200, wherein the semiconductor layer 300 has contact portion 350 and second separating channel 450 therein. The semiconductor layer 300 may be formed of a silicon-based semiconductor material. The semiconductor layer 300 may be formed in a PIN structure where a P-type semiconductor layer, an I-type semiconductor layer, and an N-type semiconductor layer are deposited in sequence. In the semiconductor layer 300 with the PIN structure, depletion is generated in the I-type semiconductor layer by the P-type semiconductor layer and the N-type semiconductor layer, whereby an electric field occurs therein. Thus, electrons and holes generated by the solar ray are drifted by the electric field, and the drifted electrons and holes are collected in the N-type semiconductor layer and the P-type semiconductor layer, respectively. If forming the semiconductor layer 300 with the PIN structure, the P-type semiconductor layer is firstly formed on the front electrode 200, and then the I-type and N-type semiconductor layers are formed thereon, preferably. This is because a drift mobility of the hole is less than a drift mobility of the electron. In order to maximize the efficiency in collection of the incident light, the P-type semiconductor layer is provided adjacent to the light-incidence face.

The transparent conductive layer 400 is formed on the semiconductor layer 300, wherein the transparent conductive layer 400 has the same pattern as the semiconductor layer 300. That is, the transparent conductive layer 400 has contact portion 350 and second separating channel 450 therein. The transparent conductive layer 400 may be formed of a transparent conductive material, for example, ZnO, ZnO:B, ZnO:Al, ZnO:H, or Ag.

The transparent conductive layer 400 may be omitted. However, the transparent conductive layer 400 is formed so as to improve the solar cell efficiency, preferably. This is because the transparent conductive layer 400 makes the solar ray dispersed in all angles, whereby the solar ray is reflected on the rear electrode 500, thereby resulting in the increase of solar ray re-incident on the semiconductor layer 300.

The contact portion 350 and the second separating channel 450 are formed by removing predetermined portions of the semiconductor layer 300 and the transparent conductive layer 400. As shown in FIG. 3(B), the contact portion 350 may be apart from the second separating channel 450. As shown in FIG. 3(C), the contact portion 350 may be in contact with the second separating channel 450. The contact portion 350 and the second separating channel 450 being in contact with each other constitute an open part 380.

A portion from the contact portion 350 to the second separating channel 450 becomes a dead zone which can not work for generating an electric power. Thus, if the contact portion 350 is in contact with the second separating channel 450, as shown in FIG. 3(C), the dead zone is relatively decreased in size, thereby improving the solar cell efficiency.

The rear electrode 500 is connected with the front electrode 200 through the contact portion 350. At this time, the plurality of rear electrodes 500 are formed at fixed intervals by each second separating channel 450 interposed in-between. The rear electrode 500 is formed of a metal material, for example, Ag, Al, Ag+Mo, Ag+Ni, or Ag+Cu. As mentioned above, the first rear electrode 510 is formed at the first direction, and the second rear electrode 520 is formed at the second direction which is different from the first direction, wherein the plurality of second rear electrodes 520 are extended from each first rear electrode 510. Having described a structural embodiment of the thin film type solar cell, and method for manufacturing the same will herein be described.

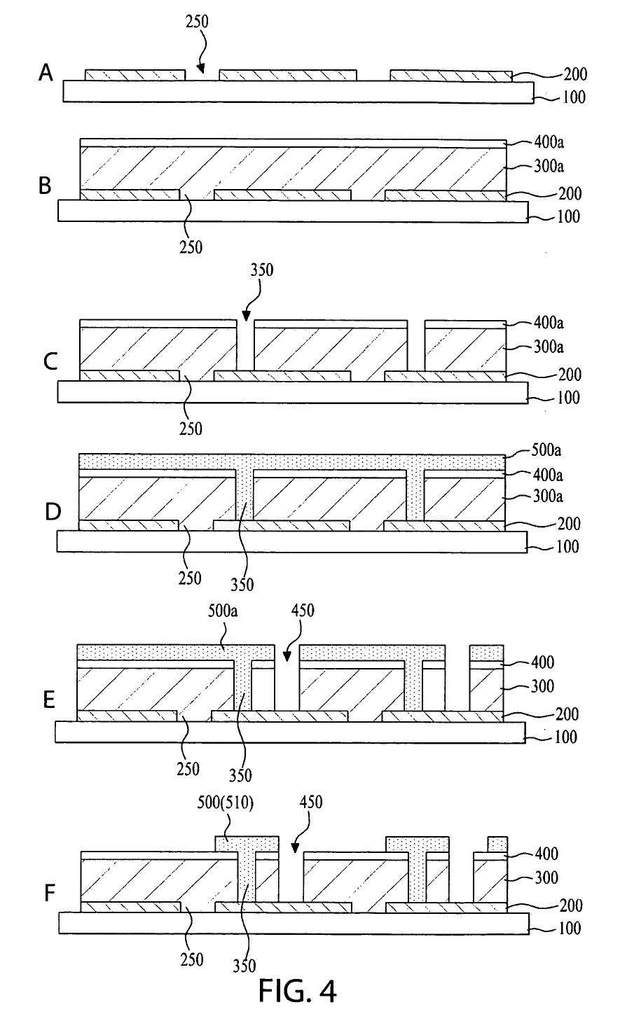

FIG. 4(A to F) is a series of cross section views illustrating a method for manufacturing a thin film type solar cell according to one embodiment of the present invention. In more detail, FIG. 4(A to F) is the series of cross section views along A-A of FIG. 3(A), wherein FIG. 4(A to F) is the series of cross section view illustrating the method for manufacturing the thin film type solar cell of FIG. 3(B).

First, as shown in FIG. 4(A), a plurality of front electrodes 200 are formed on a substrate 100, wherein the plurality of front electrodes 200 are formed at fixed intervals by each first separating channel 250 interposed in-between.

A process for forming the front electrodes 200 may comprise steps of forming a front electrode layer of a transparent conductive material, for example, ZnO, ZnO:B, ZnO:Al, SnO₂, SnO₂:F, or ITO (Indium Tin Oxide), on an entire surface of the substrate 100 by sputtering or MOCVD (Metal Organic Chemical Vapor Deposition), and forming the first separating channel 250 by removing a predetermined portion of the front electrode layer by a laser-scribing method.

Meanwhile, the plurality of front electrodes 200 may be directly formed on the substrate 100 at fixed intervals by each first separating channel 250 interposed in-between by performing a simple method such as a screen printing method, an inkjet printing method, a gravure printing method, or a micro-contact printing method.

In the case of the screen printing method, a material is transferred to a predetermined body through the use of a roller or squeegee. The inkjet printing method sprays a material onto a predetermined body through the use of an inkjet, to thereby form a predetermined pattern thereon. In the case of the gravure printing method, a material is coated on an intaglio plate, and then the coated material is transferred to a predetermined body, thereby forming a predetermined pattern on the predetermined body. The micro-contact printing method forms a predetermined pattern of material on a predetermined body through the use of a predetermined mold. If forming the front electrodes 200 through the screen printing method, the inkjet printing method, the gravure printing method, or the micro-contact printing method, there is less worry about contamination of the substrate, in comparison to the laser-scribing method, and there is no requirement for a cleaning process to prevent contamination of the substrate.

The front electrode 200 corresponds to a solar-ray incidence face. In this respect, it is important for the front electrode 200 to transmit the solar ray into the inside of the solar cell with the minimized loss. For this, a texturing process may be additionally applied to the front electrode 200.

Through the texturing process, a surface of material layer is provided with an uneven surface, that is, a texture structure, by an etching process using photolithography, an anisotropic etching process using a chemical solution, or a mechanical scribing process.

Next, as shown in FIG. 4(B), a semiconductor layer 300a and a transparent conductive layer 400a are sequentially formed on the entire surface of the substrate 100.

The semiconductor layer 300a is formed of a silicon-based semiconductor material by a plasma CVD method.

The transparent conductive layer 400a may be formed of a transparent conductive material such as ZnO, ZnO:B, ZnO:Al, or Ag by sputtering or MOCVD. The transparent conductive layer 400a may be omitted.

As shown in FIG. 4(C), the contact portion 350 is formed by removing predetermined portions of the semiconductor layer 300a and the transparent conductive layer 400a. A process for forming the contact portion 350 may be carried out by the laser-scribing method.

Next, as shown in FIG. 4(D), a rear electrode layer 500a is formed on the entire surface of the substrate 100. The rear electrode layer 500a may be formed by sputtering or printing. The rear electrode layer 500a is in contact with and connected with the front electrode 200 inside the contact portion 350.

As shown in FIG. 4(E), the second separating channel 450 is formed by removing predetermined portions of the semiconductor layer 300a, the transparent conductive layer 400a, and the rear electrode layer 500a. The semiconductor layer 300 and the transparent conductive layer 400 are formed in a predetermined pattern by the second separating channel 450. A process for forming the second separating channel 450 may be carried out by the laser-scribing method.

As shown in FIG. 4(F), a rear electrode 500 is formed by patterning the rear electrode layer 500a, wherein the rear electrode 500 is comprised of a first rear electrode (See “510” of FIG. 3(A)) and a second rear electrode (See “520” of FIG. 3(A)). The first rear electrode 510 is formed at a first direction while being connected with the front electrode 200. The second rear electrode 520 is extended from the first rear electrode 510, wherein the second rear electrode 520 is formed at a second direction which is different from the first direction. At this time, the plurality of second rear electrodes 520 extending from the first rear electrode 510 are arranged at fixed intervals. A process for patterning the rear electrode layer 500a may be carried out by photolithography.

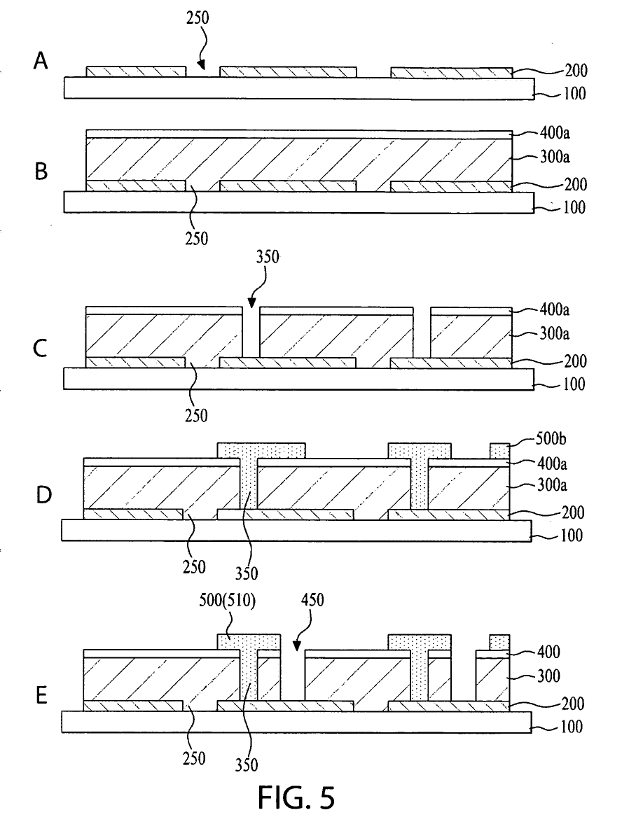

FIG. 5(A to E) is a series of cross section views illustrating a method for manufacturing a thin film type solar cell according to another embodiment of the present invention. In more detail, FIG. 5(A to F) is the series of cross section views along A-A of FIG. 3(A), wherein FIG. 5(A to F) is a series of cross section views illustrating the method for manufacturing the thin film type solar cell of FIG. 3(B). Hereinafter, a detailed explanation for the same parts as those of the aforementioned embodiment of the present invention will be omitted.

First, as shown in FIG. 5(A), a plurality of front electrodes 200 are formed on a substrate 100, wherein the plurality of front electrodes 200 are formed at fixed intervals by each first separating channel 250 interposed in-between.

As shown in FIG. 5(B), a semiconductor layer 300a and a transparent conductive layer 400a are sequentially formed on an entire surface of the substrate 100.

As shown in FIG. 5(C), a contact portion 350 is formed by removing predetermined portions of the semiconductor layer 300a and the transparent conductive layer 400a.

Next, as shown in FIG. 5(D), a rear electrode layer 500b of a predetermined pattern is formed on the substrate 100. At this time, the rear electrode layer 500b is patterned by using a predetermined mask, thereby forming a pattern for a plurality of second rear electrodes (See “520” of FIG. 3(A)). The rear electrode layer 500b of the predetermined pattern is in contact with and connected with the front electrode 200 inside the contact portion 350.

Next, as shown in FIG. 5(E), a second separating channel 450 is formed by removing predetermined portions of the semiconductor layer 300a, the transparent conductive layer 400a, and the rear electrode layer 500b. At this time, a pattern for a plurality of first rear electrodes (See “510” of FIG. 3(A)) is completed by the second separating channel 450, thereby completing a rear electrode 500 comprised of first and second rear electrodes 510 and 520.

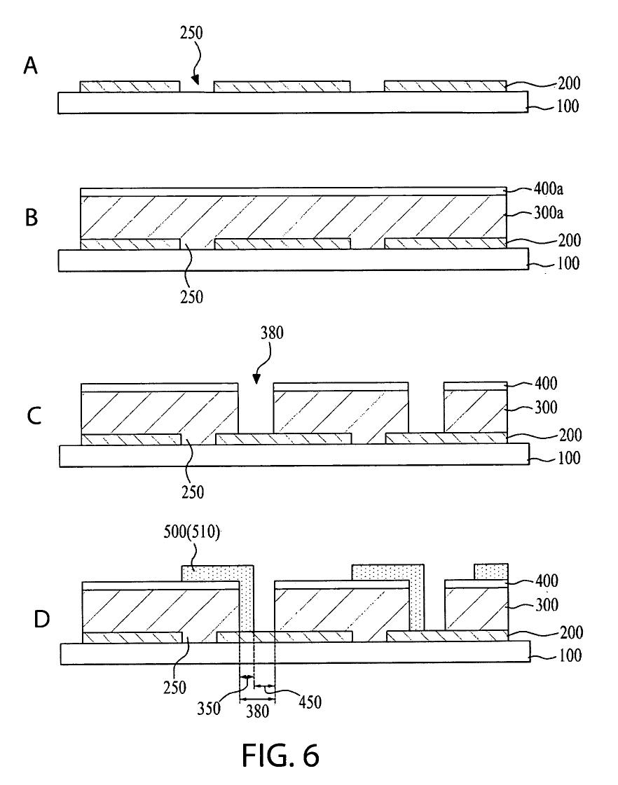

FIG. 6(A to D) is a series of cross section views illustrating a method for manufacturing a thin film type solar cell according to another embodiment of the present invention. In more detail, FIG. 6(A to D) is the series of cross section views along A-A of FIG. 3(A), wherein FIG. 6(A to D) is the series of cross section view illustrating the method for manufacturing the thin film type solar cell of FIG. 3(C). Hereinafter, a detailed explanation for the same parts as those of the aforementioned embodiment of the present invention will be omitted.

First, as shown in FIG. 6(A), a plurality of front electrodes 200 are formed on a substrate 100, wherein the plurality of front electrodes 200 are formed at fixed intervals by each first separating channel 250 interposed in-between.

As shown in FIG. 6(B), a semiconductor layer 300a and a transparent conductive layer 400a are sequentially formed on an entire surface of the substrate 100.

As shown in FIG. 6(C), an open part 380 is formed by removing predetermined portions of the semiconductor layer 300a and the transparent conductive layer 400a. The open part 380 is comprised of a contact portion 350 and a second separating channel 450. A process for forming the open part 380 may be carried out by a laser-scribing method.

As shown in FIG. 6(D), a plurality of rear electrode 500 are formed at fixed intervals by each second separating channel 450 interposed in-between, wherein the rear electrode 500 is connected with the front electrode 200 through the contact portion 350. The contact portion 350 is one portion of the open part 380, and the second separating channel 450 is the remaining portion of the open part 380.

The rear electrode 500 may be formed by a screen printing method, an inkjet printing method, a gravure printing method, or a micro-contact printing method. The rear electrode 500 may be formed of a metal material, for example, Ag, Al, Ag+Mo, Ag+Ni, or Ag+Cu.

According to the method shown in FIG. 6(A to D), it is possible to minimize the possibility for contamination in the substrate by decreasing the number of performing the laser-scribing process, and to improve the yield by decreasing the number of performing the cleaning process.

Accordingly, the thin film type solar cell according to the present invention and the method for manufacturing the same has the following advantages.

First, the rear electrode is comprised of the first and second rear electrodes, wherein the first rear electrode is formed at the first direction, and the plurality of second rear electrodes extending from each first rear electrode are formed at the second direction which is different from the first direction. Thus, the solar ray is transmitted through the portion between each of the second rear electrodes, so that it is possible to obtain the predetermined visible range. Also, the transmittance of solar ray can be adjusted by adjusting the interval between each of the second rear electrodes.

In one embodiment of the present invention, since the contact portion is in contact with the second separating channel, the solar cell efficiency can be improved by decreasing the dead zone which can not work for generating an electric power.

In one embodiment of the present invention, it is possible to minimize the possibility for contamination in the substrate by decreasing the number of performing the laser-scribing process, and to improve the yield by decreasing the number of performing the cleaning process.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A thin film type solar cell comprising:
a substrate;
a plurality of front electrodes formed on the substrate at fixed intervals by each first separating channel interposed in-between;
a semiconductor layer formed on the front electrodes, the semiconductor layer having a contact portion therein; and
a plurality of rear electrodes formed at fixed intervals by each second separating channel interposed in-between, and electrically connected with the front electrode through the contact portion,
each of said plurality of rear electrodes further comprising a first rear electrode extending along a first direction, and a plurality of second rear electrodes branching from the first rear electrode and extending along a second direction which is different from the first direction.

2. The thin film type solar cell of claim 1, wherein the plurality of second rear electrodes are arranged at fixed intervals, so that solar rays penetrate between each of the second rear electrodes.

3. The thin film type solar cell of claim 1, wherein the first rear electrode is in contact with the front electrode.

4. The thin film type solar cell of claim 1, further comprising a transparent conductive layer formed on the semiconductor layer, wherein the transparent conductive layer has the same pattern as the semiconductor layer.

5. The thin film type solar cell of claim 1, wherein the contact portion is apart from the second separating channel.

6. The thin film type solar cell of claim 1 wherein the contact portion is in contact with the second separating channel.

7. A method for manufacturing a thin film type solar cell comprising the steps of:
forming a plurality of front electrodes on a substrate, wherein the plurality of front electrodes are formed at fixed intervals by each first separating channel interposed in-between;
forming a semiconductor layer on an entire surface of the substrate;
forming a contact portion by removing a predetermined portion of the semiconductor layer; and
forming a plurality of rear electrodes at fixed intervals by each second separating channel interposed in-between, and electrically connected with the front electrode through the contact portion,
each of said plurality of rear electrodes being defined by a first rear electrode formed to extend along a first direction, and a plurality of second rear electrodes branching from the first rear electrode and formed to extend along a second direction which is different from the first direction.

8. The method of claim 7, wherein the step of forming the plurality of rear electrodes includes:
forming a rear electrode layer on the entire surface of the substrate including the semiconductor layer;
forming the second separating channel by removing predetermined portions of the semiconductor layer and the rear electrode layer; and
patterning the first and second rear electrodes by removing predetermined portions of the rear electrode layer.

9. The method of claim 7, wherein the step of forming the plurality of rear electrodes includes:
forming a rear electrode layer including a pattern for the plurality of second rear electrode; and
completing a pattern for the first rear electrode by removing predetermined portions of the semiconductor layer and the rear electrode layer for forming the second separating channel.

10. A method for manufacturing a thin film type solar cell comprising the steps of:
forming a plurality of front electrodes on a substrate, wherein the plurality of front electrodes are formed at fixed intervals by each first separating channel interposed in-between;
forming a semiconductor layer on an entire surface of the substrate;
forming an open part by removing a predetermined portion of the semiconductor layer; and
forming a plurality of rear electrodes, wherein the rear electrode is connected with the front electrode through one portion of each open part, and the plurality of rear electrodes are formed at fixed intervals by the remaining portion of each open part interposed in-between,
each of said plurality of rear electrodes being defined by a first rear electrode formed to extend along a first direction, and a plurality of second rear electrodes branching from the first rear electrode and formed to extend along a second direction which is different from the first direction.

11. The method of claim 7, wherein the step of forming the plurality of rear electrodes further comprises forming the first rear electrode being in contact with the front electrode.

12. The method of claim 10, wherein the step of forming the plurality of rear electrodes further comprises forming the first rear electrode being in contact with the front electrode.

13. The method of claim 7, wherein the step of forming the plurality of front electrodes includes:
forming a front electrode layer on the entire surface of the substrate; and
forming the first separating channel by removing a predetermined portion of the front electrode layer.

14. The method of claim 10, wherein the step of forming the plurality of front electrodes includes:
forming a front electrode layer on the entire surface of the substrate; and
forming the first separating channel by removing a predetermined portion of the front electrode layer.

15. The method of claim 7, further comprising a step of forming a transparent conductive layer on the semiconductor layer, wherein the transparent conductive layer has the same pattern as the semiconductor layer.

16. The method of claim 10, further comprising a step of forming a transparent conductive layer on the semiconductor layer, wherein the transparent conductive layer has the same pattern as the semiconductor layer.

17. The method of claims 7, wherein the contact portion is apart from the second separating channel.
